(19) United States
(12) Patent Application Publication
(10) Pub. No.: US 2014/0050039 A1
(43) Pub. Date: Feb. 20, 2014

(54) SEMICONDUCTOR MEMORY DEVICES

(71) Applicant: SK HYNIX INC., Icheon-si (KR)

(72) Inventor: Min Su PARK, Seoul (KR)

(73) Assignee: SK hynix Inc., Icheon-si (KR)

(21) Appl. No.: 13/718,983

(22) Filed: Dec. 18, 2012

(30) Foreign Application Priority Data
Aug. 20, 2012 (KR) 10-2012-0090938

(51) Int. Cl. G11C 29/04; G11C 7/06

(52) U.S. Cl. CPC G11C 29/04; G11C 7/06
USPC 365/200; 365/230.03

(57) ABSTRACT

A semiconductor memory device includes a memory bank having a first cell block including a plurality of memory cells coupled to a first word line which can be activated in response to a row address signal, a second cell block including a plurality of memory cells coupled to a second word line, and a dummy cell block including a plurality of memory cells coupled to a third word line which can be activated in response to the row address signal. The first and second cell blocks share a first sense amplifier. The second cell block and the dummy cell block share a second sense amplifier. The first cell block is disposed adjacent to a first edge of the memory bank, and the dummy cell block is disposed adjacent to a second edge of the memory bank opposing the first edge.

### CROSS-REFERENCE TO RELATED APPLICATION

The present application claims priority under 35 U.S.C 119(a) to Korean Application No. 10-2012-0090938, filed on Aug. 20, 2012, in the Korean Intellectual Property Office, which is incorporated herein by reference in its entirety as set forth in full.

### BACKGROUND

Semiconductor devices, for example, dynamic random access memory (DRAM) devices may have row address signal paths, column address signal paths, and data signal paths. The row address signals may be generated by extracting the row address from address signals inputted from an external device. The row address may be used to select a word line to allow data outputted from memory cells connected to the selected word line to be amplified using sense amplifiers. The column address signals may be generated by extracting the column address from the address signals inputted from an external device. The column address may be used to select memory cells, and can be decoded to generate an output enable signal. The data signals are used for outputting data on bit lines using the selected output enable signal, or for storing data inputted from an external device into memory cells through the bit lines.

Semiconductor memory devices may include I/O pads through which the address signals, control signals, and data signals are inputted or outputted. In general, the I/O pads may be disposed in the central regions of the layout of a semiconductor memory device. However, for semiconductor memory devices that are employed in mobile devices or systems, the I/O pads may be disposed on the edges of the layout of the semiconductor memory device. For example, I/O pads corresponding to address and control signals may be disposed on one edge of the semiconductor memory device, and I/O pads corresponding to data signals may be disposed on another edge of the semiconductor memory device.

### SUMMARY

Example embodiments are directed to semiconductor memory devices.

According to some embodiments, a semiconductor memory device includes a memory bank having a first edge and a second edge which are opposite to each other. The memory bank of the semiconductor memory device includes a first cell block including a plurality of memory cells connected to a first word line which can be activated by a row address signal, a second cell block including a plurality of memory cells connected to a second word line which can be activated by the row address signal, and a dummy cell block including a plurality of memory cells connected to a third word line which can be activated by the row address signal. The first and second cell blocks share a first sense amplifier. The second cell block and the dummy cell block share a second sense amplifier. The first cell block is disposed adjacent to the first edge of the memory bank where the row address is inputted, and the dummy cell block is disposed adjacent to a second edge of the memory bank opposing the first edge.

According to further embodiments, a semiconductor memory device includes a first memory bank and a memory second bank. The first memory bank has an upper edge and a lower edge which are opposite to each other, a first cell block and a second cell block which share a first sense amplifier, and a first dummy cell block which shares a second sense amplifier with the second cell block. The second memory bank also has an upper edge and a lower edge which are opposite to each other, a third cell block and a fourth cell block which share a third sense amplifier, and a second dummy cell block which shares a fourth sense amplifier with the fourth cell block. The first cell block is disposed adjacent to the lower edge of the first memory bank, and the first dummy cell block is disposed adjacent to the upper edge of the first memory bank. The third cell block is disposed adjacent to the upper edge of the second memory bank, and the second dummy cell block is disposed adjacent to the lower edge of the second memory bank. The lower edge of the first memory bank and the upper edge of the second memory bank are adjacent to a peripheral region through which a row address signal is inputted.

### BRIEF DESCRIPTION OF THE DRAWINGS

Embodiments of the inventive concept will become more apparent in view of the attached drawings and accompanying detailed description, in which:

FIG. 1 is a block diagram illustrating a configuration of a semiconductor memory device according to an example embodiment; and

FIG. 2 is a block diagram illustrating a configuration of a semiconductor memory device according to another example embodiment.

### DETAILED DESCRIPTION OF THE EMBODIMENTS

Example embodiments of the inventive concept will be described hereinafter with reference to the accompanying drawings. However, the example embodiments described herein are for illustrative purposes only and are not intended to limit the scope of the inventive concept.

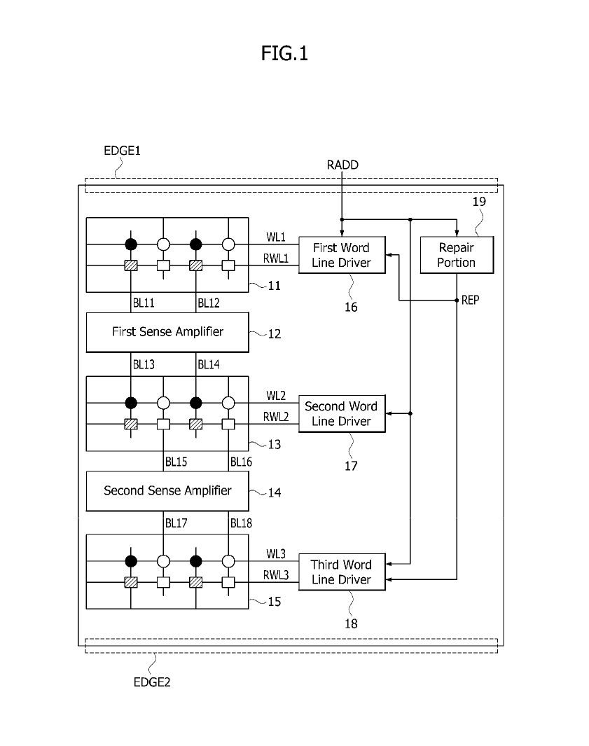

FIG. 1 is a block diagram illustrating a configuration of a memory bank of a semiconductor memory device according to an example embodiment. In some embodiments, the semiconductor memory device may include one or more memory banks, and the memory bank shown in FIG. 1 may be just one of a plurality of memory banks in the semiconductor memory device.

As illustrated in FIG. 1, the memory bank of the semiconductor memory device may include a first cell block 11, a first sense amplifier 12, a second cell block 13, a second sense amplifier 14, a dummy cell block 15, a first word line driver 16, a second word line driver 17, a third word line driver 18 and a repair portion 19. As shown, the layout of the memory bank of the semiconductor memory device may include a first edge EDGE1 and a second edge EDGE2 which are opposite to each other. In other words, the first edge EDGE1 and the second edge EDGE2 are on opposing ends of the memory bank. In some embodiments, the first word line driver 16 is placed adjacent to the first edge EDGE1 where the row address signal RADD is inputted into the memory bank.

The first cell block 11 may include a plurality of memory cells which are electrically connected to a first word line WL1 and a plurality of memory cells which are electrically connected to a first redundancy word line RWL1. Some of the memory cells (e.g., memory cells of every other bit line) in the first cell block 11 may be electrically connected to the first sense amplifier 12 through bit lines such as BL11 and BL12. When the first cell block 11 is being accessed, if no failed memory cells exist in the first cell block 11, the first word line WL1 may be selected or activated, and in response, the first sense amplifier 12 may sense and amplify the data stored in the memory cells connected to the first word line WL1. Alternatively, if at least one failed memory cell (e.g., a memory cell that cannot properly store an electrical charge and/or cannot be read or written correctly) exists in the first cell block 11, the first redundancy word line RWL1 may be selected or activated. In response, the first sense amplifier 12 may sense and amplify the data stored in the memory cells connected to the first redundancy word line RWL1.

The second cell block 13 may include a plurality of memory cells which are electrically connected to a second word line WL2 and a plurality of memory cells which are electrically connected to a second redundancy word line RWL2. Some of the memory cells (e.g., memory cells of every other bit line) in the second cell block 13 may be electrically connected to the first sense amplifier 12 through bit lines such as BL13 and BL14, and the other memory cells in the second cell block 13 may be electrically connected to a second sense amplifier 14 through bit lines such as BL15 and BL16. When the second cell block is being accessed, if no failed memory cells exist in the second cell block 13, the second word line WL2 may be selected or activated, and in response, the first and second sense amplifiers 12 and 14 may sense and amplify the data stored in the memory cells connected to the second word line WL2. Alternatively, if at least one failed memory cell exists in the second cell block 13, the second redundancy word line RWL2 may be selected or activated, and in response, the first and second sense amplifiers 12 and 14 may sense and amplify the data stored in the memory cells connected to the second redundancy word line RWL2.

The dummy cell block 15 may include a plurality of memory cells which are electrically connected to a third word line WL3 and a plurality of memory cells which are electrically connected to a third redundancy word line RWL3. In some embodiments, the dummy cell block 15 may differ from the first and second cell blocks in that the dummy cell block 15 is primarily used to provide a reference voltage when reading data from the first and/or second cell blocks. Some of the memory cells (e.g., memory cells of every other bit line) in the dummy cell block 15 may be electrically connected to the second sense amplifier 14 through bit lines such as BL17 and BL18. When the first cell block 11 is being accessed, if no failed memory cells exist in the first cell block 11, the third word line WL3 may be selected or activated, and in response, the second sense amplifier 14 may sense and amplify the data stored in the memory cells connected to the third word line WL3. Alternatively, if at least one failed memory cell exists in the first cell block 11, the third redundancy word line RWL3 may be selected or activated, and in response, the second sense amplifier 14 may sense and amplify the data which are stored in the memory cells connected to the third redundancy word line RWL3.

The first cell block 11 may share the first sense amplifier 12 with the second cell block 13, and the second cell block 13 may share the second sense amplifier 14 with the dummy cell block 15. In some embodiments, the semiconductor memory device may employ an open bit line architecture. In such embodiments, the first sense amplifier 12 may sense and amplify the data on the pair of bit lines BL11 and BL13 and the data on the pair of bit lines BL12 and BL14. The second sense amplifier 14 may sense and amplify the data on the pair of bit lines BL15 and BL17 and the data on the pair of bit lines BL16 and BL18.

The first word line driver 16 may select between the first word line WL1 or the first redundancy word line RWL1 based on the row address signal RADD and a repair signal REP. For example, when no failed memory cells exist in the first cell block 11, the repair signal REP is disabled, and the first word line driver 16 may decode the row address signal RADD to select or activate the first word line WL1. Alternatively, when at least one failed memory cell exists in the first cell block 11, the repair signal REP is enabled, and the first word line driver 16 may decode the row address signal RADD to select or activate the first redundancy word line RWL1.

The second word line driver 17 may decode the row address signal RADD to select or activate the second word line WL2 when no failed memory cells exist in the second cell block 13. Alternatively, the second word line driver 17 may decode the row address signal RADD to select or activate the second redundancy word line RWL2 when at least one failed memory cell exists in the second cell block 13.

The third word line driver 18 may select between the third word line WL3 or the third redundancy word line RWL3 based on the row address signal RADD and the repair signal REP. For example, when no failed memory cells exist in the first cell block 11, the repair signal REP is disabled, and the third word line driver 18 may decode the row address signal RADD to select or activate the third word line WL3. Alternatively, when at least one failed memory cell exists in the first cell block 11, the repair signal REP is enabled, and the third word line driver 18 may decode the row address signal RADD to select or activate the third redundancy word line RWL3. In some embodiments, the first and third word lines WL1 and WL3 may be simultaneously activated by the same row address signal RADD. This is for accessing, sensing and amplifying the data stored in the memory cells of the dummy cell block 15 connected to the second sense amplifier 14 when the memory cells that are not connected to the first sense amplifier 12 in the first cell block 11 are selected.

The repair portion 19 may include circuitry to generate the repair signal REP. The repair portion 19 may assert or enable the repair signal REP when at least one failed memory cell exists in the first cell block 11. The semiconductor memory device according to some embodiments may further include an additional repair portion (not shown) that generates an additional repair signal to control the second word line driver 17. The additional repair portion may assert or enable the additional repair signal when at least one failed memory cell exists in the second cell block 13.

As described above, the repair portion 19 may be disposed adjacent to the first edge EDGE1 where the row address RADD is inputted. Thus, the repair signal REP generated by the repair portion 19 may be transmitted to the dummy cell block 15 along a path with substantially the same routing length as the row address signal RADD. That is, an RC propagation delay time of the row address signal RADD transmitted to the third word line driver 18 may be substantially equal to that of the repair signal REP transmitted to the third word line driver 18. Accordingly, when at least one failed memory cell exist in the first cell block 11 and a repair operation is performed, the third word line driver 18 may receive the row address signal RADD and the repair signal REP at the same time to properly select or activate the third redundancy word line RWL3. As a result, a repair speed may be improved because the row address signal RADD and the repair signal REP are simultaneously transmitted to the third word line driver 18 to minimize or eliminate switching delay caused by skew between the row address signal RADD and the repair signal REP.

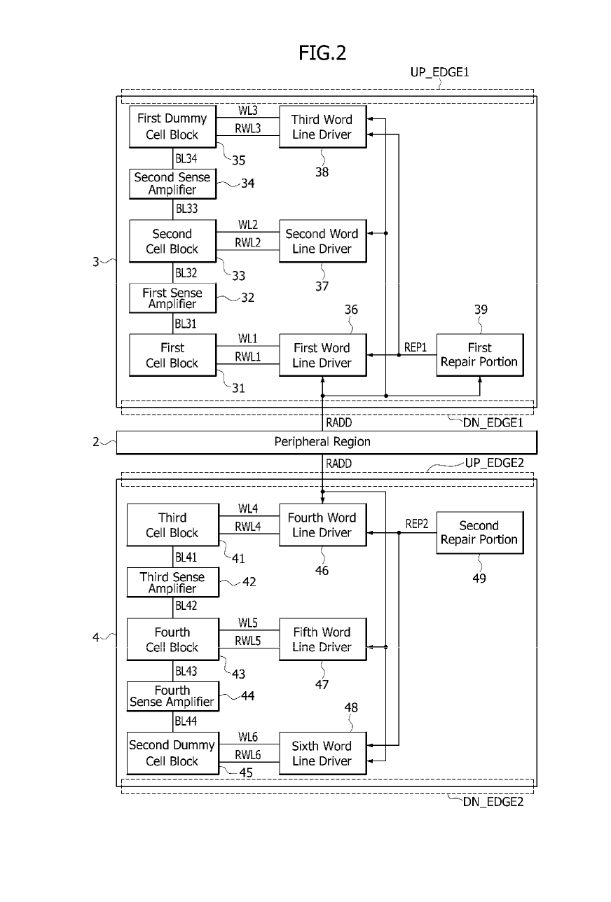

FIG. 2 is a block diagram illustrating a configuration of a semiconductor memory device according to another example embodiment.

As illustrated in FIG. 2, the semiconductor memory device may be configured to include a peripheral region 2, a first memory bank 3 and a second memory bank 4. In some embodiments, the peripheral region 2 may be disposed between the first and second memory banks 3 and 4. The peripheral region 2 may include a plurality of I/O pads through which row address signal RADD are inputted. The first memory bank 3 may include a first cell block 31, a first sense amplifier 32, a second cell block 33, a second sense amplifier 34, a first dummy cell block 35, a first word line driver 36, a second word line driver 37, a third word line driver 38 and a first repair portion 39. The second memory bank 4 may include a third cell block 41, a third sense amplifier 42, a fourth cell block 43, a fourth sense amplifier 44, a second dummy cell block 45, a fourth word line driver 46, a fifth word line driver 47, a sixth word line driver 48 and a second repair portion 49. The first memory bank 3 may receive the row address signal RADD through a first lower edge DN_EDGE1 of the first memory bank 3. The second memory bank 4 may receive the row address signal RADD through a second upper edge UP_EDGE2 of the second memory bank 4 which is adjacent to the peripheral region 2. The first dummy cell block 35 and the third word line driver 38 may be disposed adjacent to a first upper edge UP_EDGE1 of the first memory bank 3 opposite to the first lower edge DN_EDGE1. The second dummy cell block 45 and the sixth word line driver 48 may be disposed adjacent to a second lower edge DN_EDGE2 of the second memory bank 4 opposite to the second upper edge UP_EDGE2.

The first cell block 31 may include a plurality of memory cells which are electrically connected to a first word line WL1 and a plurality of memory cells which are electrically connected to a first redundancy word line RWL1. Some of the memory cells in the first cell block 31 may be electrically connected to the first sense amplifier 32 through bit lines BL31. When the first cell block 31 is being accessed, if no failed memory cells exist in the first cell block 31, the first word line WL1 may be selected or activated, and in response, the first sense amplifier 32 may sense and amplify the data stored in the memory cells connected to the first word line WL1. Alternatively, if at least one failed memory cell exists in the first cell block 31, the first redundancy word line RWL1 may be selected or activated, and in response, the first sense amplifier 32 may sense and amplify the data stored in the memory cells connected to the first redundancy word line RWL1.

The second cell block 33 may include a plurality of memory cells which are electrically connected to a second word line WL2 and a plurality of memory cells which are electrically connected to a second redundancy word line RWL2. Some of the memory cells in the second cell block 33 may be electrically connected to the first sense amplifier 32 through bit lines BL32, and the other memory cells in the second cell block 33 may be electrically connected to a second sense amplifier 34 through bit lines BL33. When the second cell block 33 is being accessed, if no failed memory cells exist in the second cell block 33, the second word line WL2 may be selected or activated, and in response, the first and second sense amplifiers 32 and 34 may sense and amplify the data stored in the memory cells connected to the second word line WL2. Alternatively, if at least one failed memory cell exists in the second cell block 33, the second redundancy word line RWL2 may be selected or activated, and the first and second sense amplifiers 32 and 34 may sense and amplify the data stored in the memory cells connected to the second redundancy word line RWL2.

The first dummy cell block 35 may include a plurality of memory cells which are electrically connected to a third word line WL3 and a plurality of memory cells which are electrically connected to a third redundancy word line RWL3. Some of the memory cells in the first dummy cell block 35 may be electrically connected to the second sense amplifier 34 through bit lines BL34. When the first cell block 31 is being accessed, if no failed memory cells exist in the first cell block 31, the third word line WL3 may be selected or activated, and in response, the second sense amplifier 34 may sense and amplify the data stored in the memory cells connected to the third word line WL3. Alternatively, if at least one failed memory cell exists in the first cell block 31, the third redundancy word line RWL3 may be selected or activated, and in response, the second sense amplifier 34 may sense and amplify the data which are stored in the memory cells connected to the third redundancy word line RWL3.

The first cell block 31 may share the first sense amplifier 32 with the second cell block 33, and the second cell block 33 may share the second sense amplifier 34 with the first dummy cell block 35. In some embodiments, the semiconductor memory device may employ an open bit line architecture. In such embodiments, the first sense amplifier 32 may sense and amplify the data on the pair of bit lines BL31 and BL32, and the second sense amplifier 34 may sense and amplify the data on the pair of bit lines BL33 and BL34.

The first word line driver 36 may select between the first word line WL1 or the first redundancy word line RWL1 based on the row address signal RADD and a first repair signal REP1. For example, when no failed memory cells exist in the first cell block 31, the first repair signal REP1 is disabled, and the first word line driver 36 may decode the row address signal RADD to select or activate the first word line WL1. Alternatively, when at least one failed memory cell exists in the first cell block 31, the first repair signal REP1 is enabled, and the first word line driver 36 may decode the row address signal RADD to select or activate the first redundancy word line RWL1.

The second word line driver 37 may decode the row address signal RADD to select or activate the second word line WL2 when no failed memory cells exist in the second cell block 33. Alternatively, the second word line driver 37 may decode the row address signal RADD to select or activate the second redundancy word line RWL2 when at least one failed memory cell exists in the second cell block 33.

The third word line driver 38 may select between the third word line WL3 or the third redundancy word line RWL3 based on the row address signal RADD and the first repair signal REP1. For example, when no failed memory cells exist in the first cell block 31, the first repair signal REP1 is disabled, and the third word line driver 38 may decode the row address signal RADD to select or activate the third word line WL3. Alternatively, when at least one failed memory cell exists in the first cell block 31, the first repair signal REP1 is enabled, and the third word line driver 38 may decode the row address signal RADD to select or activate the third redundancy word line RWL3. In some embodiments, the first and third word lines WL1 and WL3 may be simultaneously activated by the same row address signal RADD. This is for accessing, sensing and amplifying the data stored in the memory cells of the first dummy cell block 35 connected to the second sense amplifier 34 when the memory cells that are not connected to the first sense amplifier 32 in the first cell block 31 are selected.

The first repair portion 39 may include circuitry to generate the first repair signal REP1. The first repair portion 39 may assert or enable the first repair signal REP1 when at least one failed memory cell exists in the first cell block 31. The semiconductor memory device according to some embodiments may further include an additional repair portion (not shown) in the first memory bank 3 to generate an additional repair signal to control the second word line driver 37. The additional repair portion in the first memory bank 3 may assert or enable the additional repair signal when at least one failed memory cell exists in the second cell block 33.

The third cell block 41 may include a plurality of memory cells which are electrically connected to a fourth word line WL4 and a plurality of memory cells which are electrically connected to a fourth redundancy word line RWL4. Some of the memory cells in the first cell block 41 may be electrically connected to the third sense amplifier 42 through bit lines BL41. When the third cell block 41 is being accessed, if no failed memory cells exist in the third cell block 41, the fourth word line WL4 may be selected or activated, and in response, the third sense amplifier 42 may sense and amplify the data stored in the memory cells connected to the fourth word line WL4. Alternatively, if at least one failed memory cell exists in the third cell block 41, the fourth redundancy word line RWL4 is selected or activated, and in response, the third sense amplifier 42 may sense and amplify the data stored in the memory cells connected to the fourth redundancy word line RWL4.

The fourth cell block 43 may include a plurality of memory cells which are electrically connected to a fifth word line WL5 and a plurality of memory cells which are electrically connected to a fifth redundancy word line RWL5. Some of the memory cells in the fourth cell block 43 may be electrically connected to the third sense amplifier 42 through bit lines BL42, and the other memory cells in the fourth cell block 43 may be electrically connected to a fourth sense amplifier 44 through bit lines BL43. When the fourth cell block 43 is being accessed, if no failed memory cells exist in the fourth cell block 43, the fifth word line WL5 is selected or activated, and in response, the third and fourth sense amplifiers 42 and 44 may sense and amplify the data stored in the memory cells connected to the fifth word line WL5. Alternatively, if at least one failed memory cell exists in the fourth cell block 43, the fifth redundancy word line RWL5 may be selected or activated, and in response, the third and fourth sense amplifiers 42 and 44 may sense and amplify the data stored in the memory cells connected to the fifth redundancy word line RWL5.

The second dummy cell block 45 may include a plurality of memory cells which are electrically connected to a sixth word line WL6 and a plurality of memory cells which are electrically connected to a sixth redundancy word line RWL6. Some of the memory cells in the second dummy cell block 45 may be electrically connected to the fourth sense amplifier 44 through bit lines BL44. When the third cell block 41 is being accessed, if no failed memory cells exist in the third cell block 41, the sixth word line WL6 may be selected or activated, and in response, the fourth sense amplifier 44 may sense and amplify the data stored in the memory cells connected to the sixth word line WL6. Alternatively, if at least one failed memory cell exists in the third cell block 41, the sixth redundancy word line RWL6 may be selected or activated, and in response, the fourth sense amplifier 44 may sense and amplify the data which are stored in the memory cells connected to the sixth redundancy word line RWL6.

The third cell block 41 may share the third sense amplifier 42 with the fourth cell block 43, and the fourth cell block 43 may share the fourth sense amplifier 44 with the second dummy cell block 45. In some embodiments, the semiconductor memory device may employ an open bit line architecture. In such embodiments, the third sense amplifier 42 may sense and amplify the data on the pair of bit lines BL41 and BL42, and the fourth sense amplifier 44 may sense and amplify the data on the pair of bit lines BL43 and BL44.

The fourth word line driver 46 may select between the fourth word line WL4 or the fourth redundancy word line RWL4 based on the row address signal RADD and a second repair signal REP2. For example, when no failed memory cells exist in the third cell block 41, the second repair signal REP2 is disabled, and in response, the fourth word line driver 46 may decode the row address signal RADD to select or activate the fourth word line WL4. Alternatively, when at least one failed memory cell exists in the third cell block 31, the second repair signal REP2 is enabled, and in response, the fourth word line driver 46 may decode the row address signal RADD to activate the fourth redundancy word line RWL4.

The fifth word line driver 47 may decode the row address signal RADD to select or activate the fifth word line WL5 when no failed memory cells exist in the fourth cell block 43. Alternatively, the fifth word line driver 47 may decode the row address signal RADD to select or activate the fifth redundancy word line RWL5 when at least one failed memory cell exists in the fourth cell block 43.

The sixth word line driver 48 may select between the sixth word line WL6 or the sixth redundancy word line RWL6 based on the row address signal RADD and the second repair signal REP2. For example, when no failed memory cells exist in the third cell block 41, the second repair signal REP2 is disabled, and in response, the sixth word line driver 48 may decode the row address signal RADD to select or activate the sixth word line WL6. Alternatively, when at least one failed memory cell exists in the third cell block 41, the second repair signal REP2 is enabled, and in response, the sixth word line driver 48 may decode the row address signal RADD to select or activate the sixth redundancy word line RWL6. In some embodiments, the fourth and sixth word lines WL4 and WL6 may be simultaneously activated by the same row address signal RADD. This is for accessing, sensing and amplifying the data stored in the memory cells of the second dummy cell block 45 connected to the fourth sense amplifier 44 when the memory cells that are not connected to the third sense amplifier 42 in the third cell block 41 are selected.

The second repair portion 49 may include circuitry to generate the second repair signal REP2. The second repair portion 49 may assert or enable the second repair signal REP2 when at least one failed memory cell exists in the third cell block 41. The semiconductor memory device according to some embodiments may further include an additional repair portion (not shown) in the second memory bank 4 to generate an additional repair signal to control the fifth word line driver 47. The additional repair portion in the second memory bank 4 may assert or enable the additional repair signal when at least one failed memory cell exists in the fourth cell block 43.

As described above, the first memory bank 3 may be configured such that the first word line WL1 (which is connected to the first cell block 31 disposed adjacent to the first lower edge DN_EDGE1) and the third word line WL3 (which is connected to the first dummy cell block 35 disposed adjacent to the first upper edge UP_EDGE1) are simultaneously activated. Further, the second memory bank 4 may be configured such that the fourth word line WL4 (which is connected to the third cell block 41 disposed adjacent to the second upper edge UP_EDGE2) and the sixth word line WL6 (which is connected to the second dummy cell block 45 disposed adjacent to the second lower edge DN_EDGE2) are simultaneously activated. The second word line WL2 (which is connected to the second cell block 33 of the first memory bank 3) and the fourth word line WL4 (which is connected to the third cell block 41 of the second memory bank 4) may be simultaneously activated by the row address signal RADD. Further, the first word line WL1 (which is connected to the first cell block 31 of the first bank 3) and the fifth word line WL5 (which is connected to the fourth cell block 43 of the second bank 4) may be simultaneously activated by the row address signal RADD. That is, according to the present embodiment, the first word line WL1 connected to the first cell block 31, the third word line WL3 connected to the first dummy cell block 35, the fourth word line WL4 connected to the third cell block 41, and the sixth word line WL6 connected to the second dummy cell block 45 may not be simultaneously activated during a refresh operation. Thus, the semiconductor memory device according to the present embodiment may prevent four word lines from being simultaneously activated during a refresh operation. As a result, a peak current generated during the refresh operation may be reduced.

Moreover, since the first repair portion 39 is disposed adjacent to the first lower edge DN_EDGE1, the first repair signal REP1 generated by the first repair portion 39 may be transmitted to the first dummy cell block 35 along a path with substantially the same routing length as the row address signal RADD. In addition, since the second repair portion 49 is disposed adjacent to the second upper edge UP_EDGE2, the second repair signal REP2 generated in the second repair portion 49 may be transmitted to the second dummy cell block 45 along a path with substantially the same routing length as the row address signal RADD. Thus, when the failed memory cells in the first cell block 31 or the third cell block 41 are repaired, the repair operation speed may be improved because the row address signal RADD and the first repair signal REP1 (or the second repair signal REP2) are simultaneously transmitted to the third word line driver 38 (or the sixth word line driver 48) to minimize or eliminate switching delay caused by skew between the road dress signal RADD and the respective repair signal.

According to the embodiments set forth above, a repair operation speed may be improved and a refresh peak current may be reduced.

The example embodiments of the inventive concept have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A semiconductor memory device comprising:
a first cell block including a first plurality of memory cells coupled to a first word line;
a second cell block including a second plurality of memory cells coupled to a second word line; and
a dummy cell block including a third plurality of memory cells coupled to a third word line,
wherein the first and second cell blocks share a first sense amplifier, the second cell block and the dummy cell block share a second sense amplifier, the first cell block is disposed adjacent to a first edge of the semiconductor memory device where a row address signal is inputted, and the dummy cell block is disposed adjacent to a second edge of the semiconductor memory device opposing the first edge.

2. The semiconductor memory device of claim 1:
wherein when the row address signal indicates the first cell block is being accessed and no failed memory cells exists in the first cell block, the first and third word lines are simultaneously activated; and
wherein when the row address signal indicates the first cell block is being accessed and at least one failed memory cell exists in the first cell block, the first and third redundancy word lines are simultaneously activated.

3. The semiconductor memory device of claim 2, further comprising a repair portion configured to generate a repair signal to indicate if at least one failed memory cell exists in the first cell block when the row address signal indicates the first cell block is being accessed.

4. The semiconductor memory device of claim 3, wherein the repair portion is disposed adjacent to the first edge of the semiconductor memory device.

5. The semiconductor memory device of claim 4, further comprising:
a first word line driver configured to select between the first word line or a first redundancy word line based on the row address signal and the repair signal;
a second word line driver configured to select between the second word line or a second redundancy word line; and
a third word line driver configured to select between the third word line or a third redundancy word line based on the row address signal and the repair signal.

6. The semiconductor memory device of claim 5, wherein the first word line driver is disposed adjacent to the first edge of the semiconductor memory device, and the third word line driver is disposed adjacent to the second edge of the semiconductor device opposing the first edge.

7. The semiconductor memory device of claim 5, wherein when the row address signal indicates the first cell block is being accessed, the first word line driver is configured to activate the first redundancy word line when the repair signal is enabled, and to activate the first word line when the repair signal is disabled.

8. The semiconductor memory device of claim 7, wherein when the row address signal indicates the second cell block is being accessed, the second word line driver is configured to activate the second redundancy word line when at least one failed memory cell exists in the second cell block, and to activate the second word line when no failed memory cells exist in the second cell block.

9. The semiconductor memory device of claim 8, wherein when the row address signal indicates the first cell block is being accessed, the third word line driver is configured to activate the third redundancy word line when the repair signal is enabled, and to activate the third word line when the repair signal is disabled.

10. A semiconductor memory device comprising:
a first memory bank having a first upper edge and a first lower edge opposing the first upper edge, and including a first cell block disposed adjacent to the first lower edge, a second cell block, a first dummy cell block disposed adjacent to the first upper edge, a first sense amplifier shared by the first cell block and the second cell block, and a second sense amplifier shared by the second cell block and the first dummy cell block; and
a second memory bank having a second upper edge and a second lower edge opposing the second upper edge, and including a third cell block disposed adjacent to the second upper edge, a fourth cell block, a second dummy cell block disposed adjacent to the second lower edge, a third sense amplifier shared by the third cell block and the fourth cell block, and a fourth sense amplifier shared by the fourth cell block and the second dummy cell block,
wherein the first lower edge and the second upper edge are adjacent to a peripheral region through which a row address signal is inputted.

11. The semiconductor memory device of claim 10:
wherein the first cell block includes a first plurality of memory cells coupled to a first word line;
wherein the second cell block includes a second plurality of memory cells coupled to a second word line;
wherein the first dummy cell block includes a third plurality of memory cells coupled to a third word line; and
wherein the first word line and the third word line are configured to be simultaneously activated.

12. The semiconductor memory device of claim 11, wherein the first memory bank further includes a first repair portion configured to generate a first repair signal to indicate if at least one failed memory cell exists in the first cell block when the row address signal indicates the first cell block is being accessed.

13. The semiconductor memory device of claim 12, wherein the first repair portion is disposed adjacent to the first lower edge of the first memory bank.

14. The semiconductor memory device of claim 13, wherein the first bank further includes:
a first word line driver configured to select between the first word line or a first redundancy word line based on the row address signal and the first repair signal;
a second word line driver configured to select between the second word line or a second redundancy word line; and
a third word line driver configured to select between the third word line or a third redundancy word line based on the row address signal and the first repair signal.

15. The semiconductor memory device of claim 14, wherein the first word line driver is disposed adjacent to the first lower edge of the first memory bank, and the third word line driver is disposed adjacent to the first upper edge of the first memory bank.

16. The semiconductor memory device of claim 11:
wherein the third cell block includes a fourth plurality of memory cells coupled to a fourth word line;
wherein the fourth cell block includes a fifth plurality of memory cells coupled to a fifth word line;
wherein the second dummy cell block includes a sixth plurality of memory cells coupled to a sixth word line; and
wherein the fourth word line and the sixth word line are configured to be simultaneously activated.

17. The semiconductor memory device of claim 16, wherein the second memory bank further includes a second repair portion configured to generate a second repair signal to indicate if at least one failed memory cell exists in the third cell block when the row address signal indicates the third cell block is being accessed.

18. The semiconductor memory device of claim 17, wherein the second repair portion is disposed adjacent to the second upper edge of the second memory bank.

19. The semiconductor memory device of claim 18, wherein the second bank further includes:
a fourth word line driver configured to select between the fourth word line or a fourth redundancy word line based on the row address signal and the second repair signal;
a fifth word line driver configured to select between the fifth word line or a fifth redundancy word line; and
a sixth word line driver configured to select between the sixth word line or a sixth redundancy word line based on the row address signal and the second repair signal.

20. The semiconductor memory device of claim 19, wherein the fourth word line driver is disposed adjacent to the second upper edge of the second memory bank, and the sixth word line driver is disposed adjacent to the second lower edge of the second memory bank.

21. The semiconductor memory device of claim 16, wherein the first word line, the third word line, the fourth word line, and the sixth word line are prevented from being simultaneously activated during a refresh operation.

22. The semiconductor memory device of claim 16, wherein the first word line and the fifth word line are configured to be simultaneously activated.

23. The semiconductor memory device of claim 16, wherein the second word line and the fourth word line are configured to be simultaneously activated.
